(19) United States
(12) Patent Application Publication
(10) Pub. No.: US 2026/0049768 A1
(43) Pub. Date: Feb. 19, 2026

(54) SUBSTRATE PROCESSING APPARATUS

(71) Applicant: WONIK IPS CO., LTD., Pyeongtaek-si (KR)

(72) Inventor: Jeong Lim SON, Pyeongtaek-si (KR)

(21) Appl. No.: 19/266,652

(22) Filed: Jul. 11, 2025

(30) Foreign Application Priority Data
Aug. 16, 2024 (KR) 10-2024-0109908

(51) Int. Cl. F27B 17/00; F27D 1/10; F27D 9/00; F27D 11/02; H01L 21/67; H05B 3/62

(52) U.S. Cl. CPC F27B 17/0025; F27D 1/10; F27D 9/00; F27D 11/02; H01L 21/67109; H05B 3/62; F27D 2009/0002; H05B 2203/016

(57) ABSTRACT

A substrate processing apparatus comprises: an inner tube (100) forming a processing space (S1) in which a plurality of substrates are stacked and processed in a vertical direction ; a heater unit (200) installed to surround at least a portion of the inner tube (100) to form a heating space (S2) between itself and the inner tube (100), and generating heat by receiving power from outside ; and an outer tube (300) in which the heater unit (200) is disposed to form an internal space (S3) between itself and the heater unit (200), and having at least one openable/closable opening (302) formed on a side thereof to allow external access to the internal space (S3), wherein the heater unit (200) is electrically connected to a power supply unit (700) that transfers power through the outer tube (300) at a position corresponding to the opening (302).

### CROSS-REFERENCE TO RELATED APPLICATIONS

This U.S. non-provisional patent application claims priority under 35 U.S.C. § 119 of Korean Patent Application No. 10-2024-0109908, filed on Aug. 16, 2024, the entire contents of which are hereby incorporated by reference.

### FIELD OF THE INVENTION

The present invention relates to a substrate processing apparatus, and more particularly, to a substrate processing apparatus in which a high-pressure process is performed.

### BACKGROUND ART

A substrate processing apparatus is an apparatus that processes a substrate such as a wafer, and a reactor using a boat may be used to perform one or more processes such as deposition, etching, and heat treatment on a plurality of substrates.

In such a conventional reactor-type substrate processing apparatus, a single or double tube, into which a plurality of substrates are inserted by a boat to perform substrate processing, is applied, and a heater is provided at the outermost part to supply heat to form process temperature atmosphere.

Meanwhile, for various processes on a substrate, particularly for annealing process that improves film quality through recrystallization of the substrate surface by removing residues remaining on and within the substrate surface, it may be necessary to perform substrate processing by creating high temperature of 800° C. or more and high pressure of 2 ATM or more, as required.

However, conventional substrate processing apparatuses applied a double tube for protection in case of tube breakage due to the creation of high-pressure state of 2 ATM or more. However, in the case of quartz material, there is a problem that its durability is weak due to high risk of damage under high-pressure environment, and contamination due to gas leakage may occur in case of damage.

Furthermore, if the material of the double tube is reinforced in response to this, there is a problem that sufficient high-temperature condition for substrate processing is difficult to achieve, as the heat transfer rate is low due to the material, making it difficult to receive heat from a heater located at the outermost part.

Accordingly, a heater was placed inside the tube to increase heating efficiency for process temperature with sufficient rigidity against high pressure. However, in this case, there is a problem that maintenance and management for the heater unit are difficult.

In particular, the connection part with the terminals and power lines provided for applying power to the heater unit from outside is a contact part, so issues such as damage and poor contact may frequently occur, and accordingly, maintenance and management are essential. However, since the heater is placed inside the tube, there is a problem that access to and maintenance of the heater unit are difficult.

### SUMMARY OF THE INVENTION

The object of the present invention is to provide a substrate processing apparatus that facilitates maintenance of an internal heater unit in order to solve the above problems.

The present invention has been created to achieve the above object of the present invention. The present invention discloses a substrate processing apparatus comprising: an inner tube (100) forming a processing space (S1) in which a plurality of substrates are stacked and processed in a vertical direction ; a heater unit (200) installed to surround at least a portion of the inner tube (100) to form a heating space (S2) between itself and the inner tube (100), and generating heat by receiving power from outside ; and an outer tube (300) in which the heater unit (200) is disposed to form an internal space (S3) between itself and the heater unit (200), and having at least one openable/closable opening (302) formed on a side thereof to allow external access to the internal space (S3), wherein the heater unit (200) is electrically connected to a power supply unit (700) that transfers power through the outer tube (300) at a position corresponding to the opening (302).

The heater unit (200) may have its connection part with the power supply unit (700) exposed when the opening (302) is opened.

The heater unit (200) may include a side insulation part (210) disposed to surround the inner tube (100), a heating part (220) provided on the inner surface of the side insulation part (210) to generate heat according to the applied power, and a terminal part (240) provided on the outer surface of the side insulation part (210) and electrically connected to both ends of the heating part (220).

The terminal part (240) may be provided at a height corresponding to the opening (302).

The terminal part (240) may include a connection terminal (241) provided on the outer surface of the side insulation part (210) to be coupled to the heating part (220), and a connection rod (242) extending from the connection terminal (241) to the opening (302) and coupled to the power supply unit (700).

The connection rod (242) may be extended such that an end thereof, which is coupled to the power supply unit (700) from the connection terminal (241) provided at a position offset from the opening (302), is located at a position corresponding to the opening (302).

The connection terminal (241) and the connection rod (242) may be integrally formed.

The opening (302) may be formed at a height corresponding to the terminal part (240).

A plurality of the connection terminals (241) are disposed to overlap in a planar direction in the vertical direction, and the connection rod (242) may include at least one of a horizontal rod (242a) extending in a horizontal direction and a vertical rod (242b) extending in a vertical direction to prevent overlap with the remaining connection terminals (241) except for the extended connection terminal (241).

A plurality of the terminal parts (240) are provided, and at least one may be provided per heating region for a plurality of heating regions separated in a vertical direction.

A plurality of the terminal parts (240) may correspond to a single opening (304).

A plurality of the openings (304) may be provided in a vertical direction on the outer surface of the outer tube (300).

The outer tube (300) may include a vessel part (310) forming the internal space (S3) and having the opening (302) formed on a side thereof, a side flange (360) provided in the vessel part (310) at a position corresponding to the opening (302), and a door part (370) installed on the side flange (360) to open and close the opening (302).

The outer tube (300) may include at least one first connector part (350) provided on a side thereof, to which the power supply unit (700) is connected to transfer power from outside to the heater unit (200).

The first connector part (350) may electrically connect an external power supply line (710) connected from outside the outer tube (300) of the power supply unit (700), and an internal power supply line (720) disposed and connected in the internal space (S3).

The outer tube (300) may include at least one second connector part (390) provided on a side thereof for electrical connection between a temperature sensor installed to penetrate the heater unit (200) and the outside.

The apparatus may further include a cooling unit (600) provided on at least a portion of the outer surface of the outer tube (300) and having heat medium flowing therein.

The internal space (S3) and the heating space (S2) may communicate with each other.

The inner tube (100) may include quartz, and the outer tube (300) may include Steel Use Stainless (SUS).

The internal space (S3) may be maintained at higher pressure than the processing space (S1).

The heating space (S2) may maintain temperature of 800° C. or more during at least a portion of the process performed in the processing space (S1).

The internal space (S3) may maintain pressure of 2 ATM or more during at least a portion of the process performed in the processing space (S1).

The substrate processing apparatus according to the present invention has the advantage that the protection function is improved as a processing vessel that can be used without damage even at high pressure of 2 ATM or more is applied to the outermost part, and heating efficiency is increased through the proximity of the heater unit to the inner tube.

Further, the substrate processing apparatus according to the present invention has the advantage that the heater unit disposed inside the outer tube is easily accessible through an openable/closable opening provided on the side of the processing vessel, thereby facilitating maintenance and management of the heater unit.

In particular, the terminal part connected to the power supply unit for supplying power to the heater unit is connected to the power supply unit at a height corresponding to the opening, which has the advantage of facilitating maintenance and management of the contact part.

### BRIEF DESCRIPTION OF THE DRAWINGS

FIG. 1 is a perspective view showing a substrate processing apparatus according to the present invention.

FIG. 2 is a front view showing the appearance of the substrate processing apparatus according to FIG. 1.

FIG. 3 is an enlarged view showing the appearance of the opening in the substrate processing apparatus according to FIG. 2.

FIG. 4 is a cross-sectional view showing the appearance of the substrate processing apparatus according to FIG. 1.

### BRIEF DESCRIPTION OF THE DRAWINGS

Hereinafter, the substrate processing apparatus according to the present invention will be described in detail with reference to the accompanying drawings.

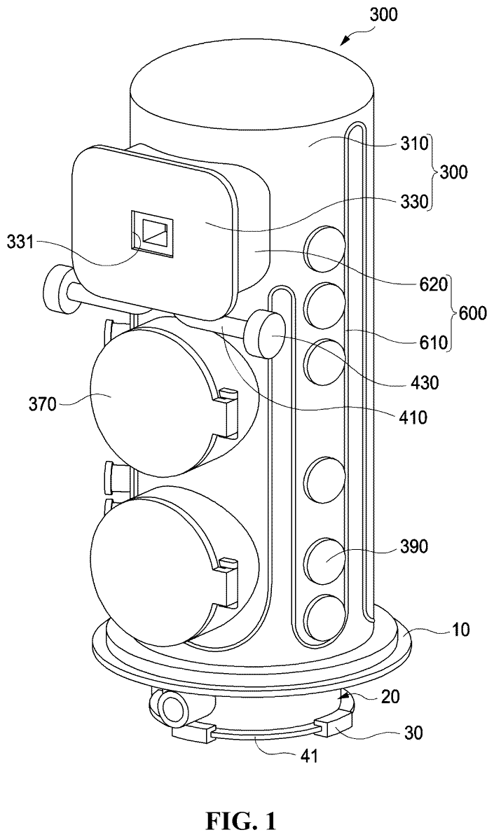

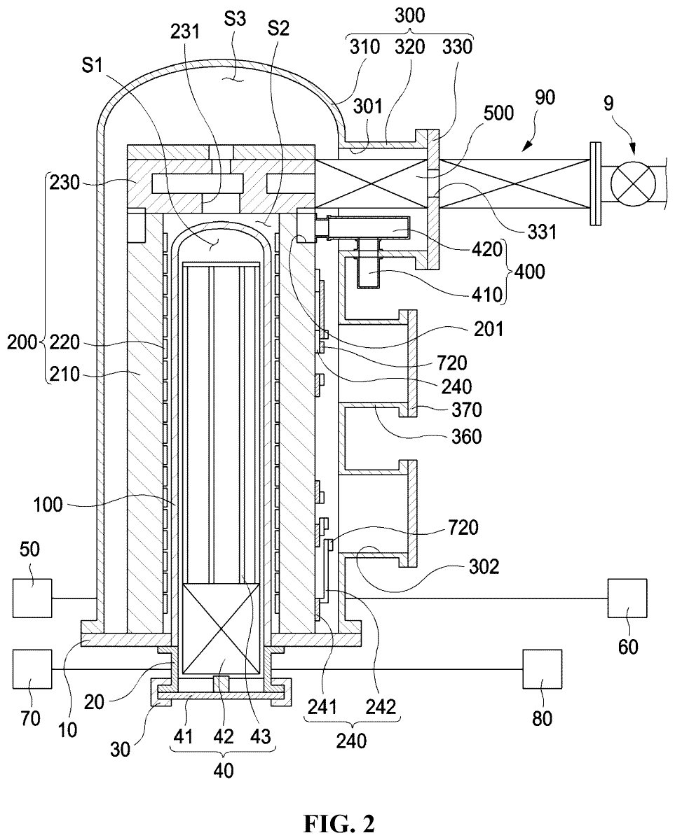

As shown in FIGS. 1 and 2, the substrate processing apparatus according to the present invention includes: an inner tube (100) forming a processing space (S1) in which a plurality of substrates are stacked and processed in a vertical direction ; a heater unit (200) installed to surround at least a portion of the inner tube (100) to form a heating space (S2) between itself and the inner tube (100), and generating heat by receiving power from outside ; and an outer tube (300) in which the heater unit (200) is disposed to form an internal space (S3) between itself and the heater unit (200), and having at least one openable/closable opening (302) formed on a side thereof to allow external access to the internal space (S3).

Further, the present invention includes a cooling gas supply unit (400) that supplies cooling gas to the heating space (S2).

Further, the present invention may further include a damper unit (500) that transfers exhaust gas discharged from the heating space (S2) to the outside.

Further, the present invention may further include a cooling unit (600) provided on at least a portion of the outer surface of the outer tube (300) and having heat medium flowing therein.

Here, the substrate to be processed can be understood to include all substrates, such as display substrates used in display devices like LEDs, LCDs, OLEDs, semiconductor substrates, solar cell substrates, and glass substrates.

Further, any conventionally disclosed process can be applied as the process performed by the substrate processing apparatus according to the present invention, as long as it is a process for treating a substrate. For example, processes such as deposition, etching, and heat treatment can be performed.

For example, the substrate processing apparatus according to the present invention can perform annealing to improve the film quality of a substrate such as a wafer, and in particular, it can effectively improve film quality by promoting recrystallization or migration of the substrate surface through effective removal of impurities remaining on or weakly bonded to the surface and interior of the substrate or thin film.

In this case, the substrate processing apparatus according to the present invention can repeatedly perform a high-pressure process, for example, high pressure of 2 ATM or more, which is higher than atmospheric pressure, in the processing space (S1) where substrate processing is performed, and a low-pressure process in a vacuum state, i.e., lower than atmospheric pressure. If necessary, heat treatment at high temperature of 800° C. or more can be performed.

The inner tube (100) is a component that forms a processing space (S1) therein, and various configurations are possible.

In this case, the inner tube (100) may be a vertical cylindrical shape with a dome-shaped ceiling, forming a processing space (S1) therein, with its lower part open so that a boat (40) loaded with a plurality of substrates, described later, can be loaded and unloaded.

That is, the inner tube (100) has its lower part open, allowing a boat (40) loaded with a plurality of substrates to be inserted through the lower part, thereby forming a sealed processing space (S1) where substrate processing can be performed. After the substrate processing is completed, the boat (40) can be lowered and unloaded.

In this case, the boat (40) may include a support part (43) that supports a plurality of substrates spaced apart vertically, an insulation part (42) provided below the support part (43) to prevent heat loss from the processing space (S1) to the outside, and a cap flange (41) below the insulation part (42) that supports the insulation part (42) and the substrate support part (43).

Accordingly, when the boat (40) is raised and loaded into the processing space (S1) within the inner tube (100), the cap flange (41) can be in close contact with the lower end of the manifold (20), and they can be coupled to each other through a clamp (30) that clamps the edges of the cap flange (41) and the lower end of the manifold (20) to form a sealed processing space (S1).

In particular, the clamp (30), by clamping and fixing the manifold (20) and the cap flange (41), prevents the cap flange (41) from moving downward due to the internal high pressure when a high-pressure process of 2 ATM or more is performed in the processing space (S1), and can maintain the sealed state of the processing space (S1).

Meanwhile, the inner tube (100) may be supported by a manifold (20) installed at its open lower end and communicate with the manifold (20). In this case, process gas can be received from an external first gas supply unit (80) through a supply port formed in the manifold (20).

Further, the inner tube (100) may have process gas discharged to the external first gas exhaust unit (70) through an exhaust port formed in the manifold (20), thereby exhausting the processing space (S1).

The inner tube (100) is a non-metallic material, which may be made of quartz, and as described above, it may have a dome-shaped ceiling, but it is not limited thereto, and it may also be configured in a cylindrical shape with a flat ceiling.

The heater unit (200) may be configured to surround at least a portion of the inner tube (100) and form a heating space (S2) between itself and the inner tube (100).

That is, the heater unit (200) may be configured to have the inner tube (100) disposed inside it, forming a heating space (S2) between itself and the inner tube (100), and heating it to form the interior of the processing space (S1) into a process temperature atmosphere.

To this end, the heater unit (200) may include a side insulation part (210) disposed to surround the inner tube (100), a heating part (220) provided on the inner surface of the side insulation part (210) to generate heat according to applied power, and an upper insulation part (230) provided on the upper end of the side insulation part (210), having an exhaust flow path (231) formed therein for discharging exhaust gas from the heating space (S2), and coupled to the damper unit (500).

Further, the heater unit (200) may include a terminal part (240) provided on the outer surface of the side insulation part (210) and electrically connected to both ends of the heating part (220).

The side insulation part (210) is a component disposed to surround the inner tube (100) and may form the side surface of the heater unit (200).

In this case, the side insulation part (210) may be configured to form its side surface through a plurality of insulating materials, and the heating part (220) may be disposed on its inner surface to concentrate heat into the heating space (S2) and the processing space (S1) and minimize heat loss to the outside of the side insulation part (210).

Further, the side insulation part (210) may be formed by stacking a plurality of annular members, and in this case, a plurality of gas supply ports (not shown) may be formed to penetrate radially between or in the annular members, so that the internal space (S3) and the heating space (S2) communicate with each other, and cooling gas supplied from the cooling gas supply unit (400) can be guided to be transferred into the heating space (S2).

The heating part (220) is a component provided on the inner surface of the side insulation part (210) to generate heat according to applied power, and various configurations are possible.

In this case, the heating part (220) is a component that generates heat through resistance heat generated by a resistor to which electric power is applied, and the amount of heat generation and temperature can be adjusted by appropriately controlling the applied power. For example, the heating part (220) may be a heating wire installed inside of the side insulation part (210).

Meanwhile, the heating part (220) may be provided in a plurality of units in the vertical direction on the inner surface of the side insulation part (210), and its ends may penetrate the side insulation part (210) to receive power from the outside through the terminal part (240) provided outside the side insulation part (210).

The upper insulation part (230) may be configured to be provided on the upper end of the side insulation part (210) and have an exhaust flow path (231) formed therein for discharging exhaust gas from the heating space (S2).

That is, the upper insulation part (230) is a component that forms the upper end and ceiling of the heater unit (200), and by being provided on the upper end of the side insulation part (210) including a plurality of insulation plates, it can prevent heat loss upwards from the heating space (S2).

Meanwhile, the upper insulation part (230) may have an exhaust flow path (231) formed for the external discharge of cooling gas supplied to the heating space (S2). For example, the exhaust flow path (231) may be formed to extend from an exhaust port formed on the bottom surface of the upper insulation part (230), i.e., the ceiling surface of the heater unit (200), to the side surface of the upper insulation part (230), thereby guiding the exhaust gas, which is the cooling gas that has completed heat exchange, to be discharged to the outside.

In this case, the upper insulation part (230) may have a damper unit (500), described later, coupled to its side so as to communicate with the exhaust flow path (231). This can guide the exhaust gas, which is cooling gas supplied to the heating space (S2) and has performed heat exchange, to be transferred to the damper unit (500) through the exhaust flow path (231).

Further, the heater unit (200) may include a cover part disposed at the outermost part of the side insulation part (230) and having a through-hole formed therein to communicate with a cooling gas supply unit (400), described later, and a connecting flange formed to protrude corresponding to the through-hole of the cover part and coupled to the cooling gas supply unit (400).

In this case, the cover part is a component forming the outermost surface of the heater unit (200), and may be configured as an insulating material like the side insulation part (210) and disposed at the outermost part, or as another example, it may be applied as a cover provided to wrap the side insulation part (210).

The cover part may be configured to have a through-hole formed therein to communicate with the cooling gas supply unit (400). In particular, the through-hole may be formed at a position corresponding to a groove (201) formed on the outer surface of the side insulation part (210) with an inward step, and communicating with the heating space (S2), thereby transferring cooling gas from the cooling gas supply unit (400) toward the groove (201).

Accordingly, the cover part may form a cooling gas supply flow path between itself and the groove (201) formed along the circumference of the heater unit (200).

Meanwhile, the connecting flange protrudes from the outside of the cover part corresponding to the through-hole, and may be coupled to a cooling gas supply unit (400) described later.

In this case, a sealing member (not shown) may be provided between the connecting flange and the cooling gas supply unit (400).

Meanwhile, the heater unit (200) is electrically connected to a power supply unit (700) that transfers power through the outer tube (300) at a position corresponding to an opening (302) described later.

That is, the heater unit (200) may be electrically connected at a position corresponding to an opening (302) formed in a vessel part (310) of an outer tube (300) described later. This allows the connection part between the power supply unit (700) and the heater unit (200) to be exposed when the opening (302) is opened.

As a result, the connection part between the power supply unit (700) and the heater unit (200) is exposed and easily accessible when the opening (302) is opened, which has the advantage of facilitating maintenance and management of the connection part as a contact part with power.

To this end, the terminal part (240) is a component provided on the outer surface of the side insulation part (210) and electrically connected to both ends of the heating part (220). Various configurations are possible.

That is, the terminal part (240) is a component connected to the power supply unit (700) to apply power to the aforementioned heating part (220). It may be electrically connected to both ends of the heating part (220) that penetrates the side insulation part (210) as a side of the heater unit (200) and installed on the outer surface of the side insulation part (210), or may be installed to penetrate the side insulation part (210) from outside the side insulation part (210) and connected to both ends of the heating part (220).

Meanwhile, in this case, the terminal part (240) may be provided at a height corresponding to an opening (302) formed on the outer surface of a vessel part (310) described later.

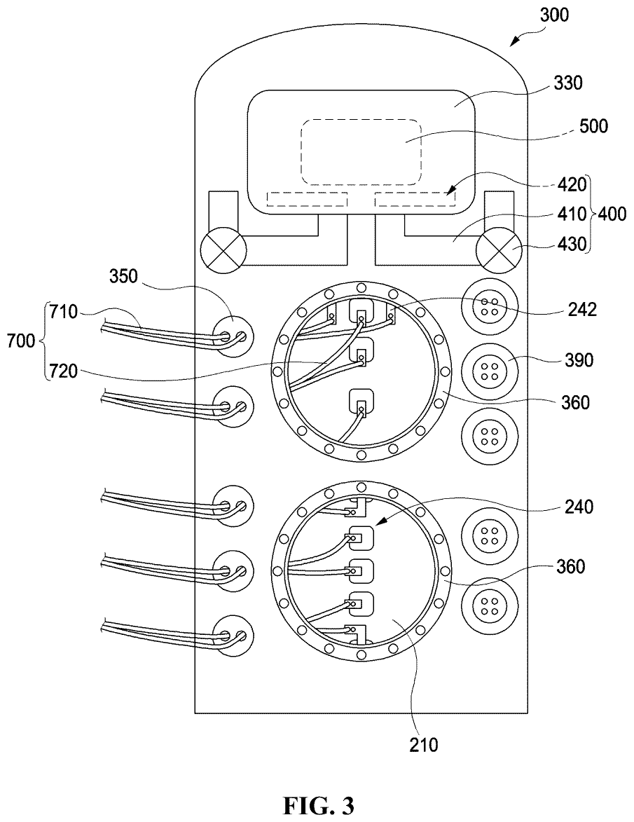

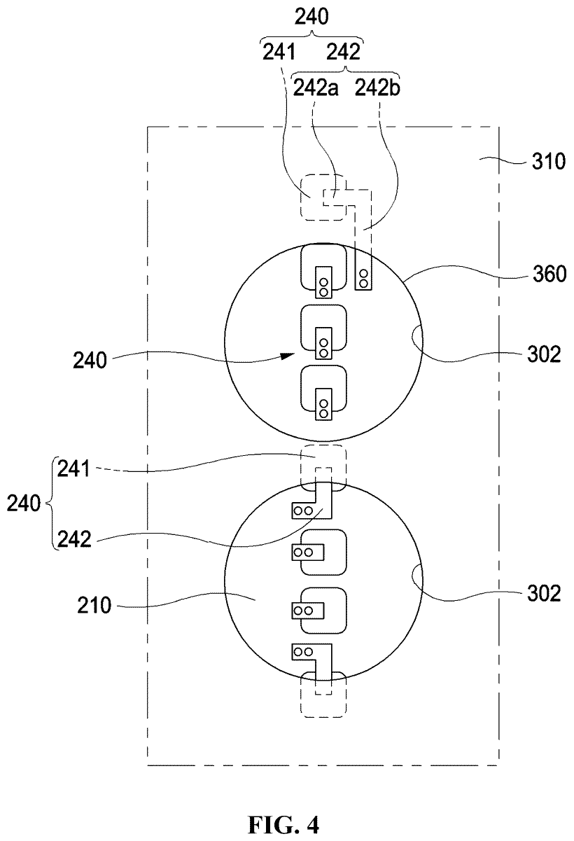

Further, as another example, as shown in FIGS. 3 and 4, the terminal part (240) may include a connection terminal (241) provided on the outer surface of the side insulation part (210) to be coupled to the heating part (220), and a connection rod (242) extending from the connection terminal (241) to the opening (302) and coupled to the power supply unit (700).

That is, a plurality of the terminal parts (240) may be provided spaced apart from each other in the vertical direction corresponding to the side insulation part (210) and the heating part (220) that are stacked in the vertical direction. Accordingly, if it is not located at a height corresponding to the opening (302), a connection rod (242) may be additionally provided such that the connection point with the power supply unit (700) is located at a height corresponding to the opening (302).

Accordingly, the connection terminal (241) may be configured to be disposed spaced apart in the vertical direction on the outer surface of the heater unit (200) so as to be coupled to the heating part (220) on the outer surface of the side insulation part (210), and the connection rod (242) may be configured to extend from the connection terminal (241) to the opening (302) and coupled to the power supply unit (700).

Meanwhile, in this case, the connection terminal (241) and the connection rod (242) may be integrally formed to prevent connection failures at points other than the connection part between the power supply unit (700) and the terminal part (240), which are difficult to access from the opening (302).

Further, as another example, it is also possible that the connection terminal (241) and the connection rod (242) may be applied as separate members coupled to each other.

Meanwhile, a plurality of the terminal parts (240) are provided, and at least one may be provided per heating region for a plurality of heating regions separated in a vertical direction.

In this case, some of the plurality of terminal parts (240) may be provided only as connection terminals (241) and omit the connection rod (242) as they are located at a height corresponding to the opening (302). Terminal parts (240) located at a height not corresponding to the opening (302) may be provided with connection terminals (241) and connection rods (242) such that the connection part with the power supply unit (700) is exposed through the connection rod (242) when the opening (302) is opened.

Accordingly, the length and shape of the connection rod (242) may vary depending on the distance between the position of the terminal part (240) and the opening (302). In particular, considering the terminal parts (240) arranged to overlap in a planar direction in the vertical direction, the connection rod (242) may be composed of a combination of a horizontal rod (242a) and a vertical rod (242b).

That is, the connection rod (242) may include a horizontal rod (242a) extending in a horizontal direction and a vertical rod (242b) extending in a vertical direction to prevent overlap with the remaining connection terminals (241) except for the extended connection terminal (241).

Meanwhile, the opening (304) may have a certain area so as to correspond to a plurality of terminal parts (240). As another example, a plurality of openings (304) may be formed at heights corresponding to each of the plurality of terminal parts (240).

Although the aforementioned terminal part (240) has been described as being formed on the outer surface of the side insulation part (210), it is not limited thereto. If the aforementioned heater unit (200) is provided with the aforementioned cover part, it may be installed on the outer surface of the cover part and electrically connected to the heating part (220) by penetrating the cover part and the side insulation part (210).

The outer tube (300) is a component in which the inner tube (100) and the heater unit (200) are disposed, and forms an internal space (S3) between itself and the heater unit (200). Various configurations are possible.

That is, the outer tube (300) is a component installed to surround the heater unit (200), which can form an internal space (S3) between itself and the heater unit (200), and can be a vertical cylindrical structure with a dome-shaped ceiling, corresponding to the aforementioned inner tube (100).

Meanwhile, the outer tube (300) may be disposed outside the inner tube (100), where high-temperature and high-pressure substrate processing is performed, and the heater unit (200), which surrounds the inner tube (100), thereby forming an internal space (S3) as a protective space. Accordingly, it can be configured to prevent external leakage of process gas due to damage to the inner tube (100) during high-pressure substrate processing and to have sufficient rigidity against high pressure.

To this end, the outer tube (300) may be made of a metal material, and for example, may include SUS.

Meanwhile, the internal space (S3) formed between the outer tube (300) and the heater unit (200) can be maintained at higher pressure than the processing space (S1) to act as a protective space, as described above. Since the heater unit (200) is not sealed and allows gas to pass through, it can communicate with the heating space (S2).

That is, the internal space (S3) can be maintained at pressure of 2 ATM or more during at least a portion of the process performed in the processing space (S1), and when the heating space (S2) is maintained at temperature of 800° C. or more during at least a portion of the process performed in the processing space (S1) due to the heating of the heating space (S2), it can be maintained at similar temperature condition.

Meanwhile, the outer tube (300) has one or more separate supply ports and one or more exhaust ports formed on its side, and each is connected to a second gas supply unit (60) and a second gas exhaust unit (50) to receive gas into the internal space (S3) from outside and to exhaust the internal space (S3).

Further, the heater unit (200) and the outer tube (300) are each configured with an open lower end, and their open lower ends can be supported and installed on a base unit (10). In this case, the aforementioned manifold (20) can be coupled and installed on the bottom surface of the base unit (10).

Meanwhile, the outer tube (300) includes a vessel part (310) in which the heater unit (200) is disposed, forming an internal space (S3) between itself and the heater unit (200), and having an opening (301) formed on a side to allow external access to the internal space (S3), and an opening/closing part provided in the vessel part (310) to open and close the opening (301).

The vessel part (310) is a component that forms the internal space (S3) and has an opening (301) formed on its side, and various configurations are possible.

For example, the vessel part (310) may be made of SUS material and have a dome-shaped ceiling, and may be provided such that the heater unit (200) and the inner tube (100) are inserted therein. Its lower end may be open and supported and installed on the base unit (100).

In this case, the vessel part (310) may have an opening (301) formed on its side, which allows access for maintenance of the damper unit (500) installed in the internal space (S3) for external discharge of cooling gas supplied to the heating space (S2).

The flange part (320) may be formed as a component protruding from the vessel part (310) at a position corresponding to the opening (301), and the opening/closing door part (330) may be installed to open and close the opening (301).

In this case, the opening/closing door part (330) may be configured to be coupled to and separable from the flange part (320) with a first sealing member (332) interposed therebetween, thereby closing and opening the opening (301).

Meanwhile, the opening/closing door part (330) may be coupled to the flange part (320) via bolting with a first sealing member (332) interposed therebetween. A hinge part may be provided at one end, allowing the opening (301) to be opened by hinge rotation after the bolts are loosened.

Further, the opening/closing door part (330) may further include a door opening (331) formed therethrough to allow communication between a damper unit (500), described later, and the outside.

That is, with the door opening (331) formed therethrough, the opening/closing door part (330) can have the damper unit (500) coupled to its inner surface to cover the door opening (331), and an external pipe coupled to its outer surface to cover the door opening (331), thereby allowing communication between the damper unit (500) and the heat exchange module (90).

Further, the opening/closing door part (330) and the flange part (320) where the opening/closing door part (330) is installed may be formed in a rectangular shape when viewed from the front, corresponding to the damper unit (500) described later.

Further, the outer tube (300) according to the present invention may further include at least one additional opening (302) formed on the outer surface of the vessel part (310) in addition to the aforementioned opening (301), and a side flange (360) and a door part (370) installed on the side flange (360) to open and close the opening (302) corresponding to the opening (302).

That is, the vessel part (310) may have at least one additional opening (302) formed below the opening (301) formed on its side to allow access to the internal space (S3), and a side flange (360) and a door part (370) for opening and closing the opening (302) may be further provided.

In this case, the side flange (360) and the door part (370) are components for maintenance and management of the heater unit (200) through access to the internal space (S3). In particular, they may be provided to allow access for maintenance and management of terminal parts and power supply parts installed to supply power to the heater unit (200).

That is, the outer tube (300) includes a side flange (360) provided in the vessel part (310) at a position corresponding to the opening (302), and a door part (370) installed on the side flange (360) to open and close the opening (302). By providing the connection part of the aforementioned terminal part (240) and the power supply unit (700) at a position corresponding to the opening (302), maintenance for the heater unit (200), including the terminal part (240), can be easily performed through the opening of the door part (370).

In this case, the side flange (360) and the door part (370) are circular in front view and may be provided as at least one, for example, two, spaced apart from each other below the aforementioned flange part (320) corresponding to the opening (302).

In this case, the description of the aforementioned flange part (320) and opening/closing door part (330) can be applied to the side flange (360) and the door part (370), so redundant descriptions are omitted.

Further, the outer tube (300) may include at least one first connector part (350) provided on a side thereof, to which the power supply unit (700) is connected to transfer power from outside to the heater unit (200), and at least one second connector part (390) provided on a side thereof for electrical connection between a temperature sensor (not shown) installed to penetrate the heater unit (200) and the outside.

In this case, the first connector part (350) and the second connector part (390) are feedthroughs provided to enable electrical connection between the inside and outside while maintaining sealing for the internal space (S3), and a plurality of them may be provided in the vessel part (310), respectively.

The first connector part (350) may be configured to electrically connect an external power supply line (710) connected from outside the outer tube (300) of the power supply unit (700), and an internal power supply line (720) disposed and connected in the internal space (S3). In this case, the internal power supply line (720) may be connected to the external power supply line (710) to receive power and supply it to the terminal part (240).

At least one second connector part (390) may be provided for electrical connection between a temperature sensor installed to penetrate the heater unit (200) on a side thereof and the outside, and a plurality of them may be provided in the vertical direction corresponding to a plurality of temperature sensors provided in the vertical direction by penetrating the side of the heater unit (200).

In this case, the second connector part (390) may be provided with a power line for supplying power to the temperature sensor, a signal line for transmitting and receiving signals about temperature sensor values, and the like, to enable electrical connection between the outside and the temperature sensor.

The damper unit (500) may have one end coupled to the upper insulation part (230) so as to communicate with the exhaust flow path (231), and the other end coupled to the opening/closing door part (330). Various configurations are possible.

The damper unit (500) is a component installed between the heater unit (200) and the external heat exchange module to communicate the heating space (S2) and the heat exchange module. Various configurations are possible.

For example, at least a portion of the damper unit (500) may be disposed within the flange part (320). One end of the damper unit (500) may be coupled to the heater unit (200), and the other end of the damper unit (500) may be coupled to the opening/closing door part (330) by covering the door opening (331) so as to communicate with the external heat exchange module.

In this case, the damper unit (500) may include a damper body in which a flow path for exhaust gas is formed, and a flow rate adjusting unit provided in the damper body to adjust the degree of opening of the flow path.

More specifically, the damper unit (500) may have a damper body in which a flow path for exhaust gas discharged through the exhaust flow path (231) is formed. One end of the damper body may be coupled to an exhaust flow path flange (232) formed on the side wall of the upper insulation part (230) so as to communicate with the exhaust flow path (231), and the other end may be coupled to the opening/closing door part (330).

In this case, the damper unit (500), as a flow rate adjusting unit, may include a driving unit that generates power, such as a motor or actuator, to drive a blade, and a blade that controls the exhaust gas flow in the flow path through the driving unit, thereby appropriately adjusting the flow rate of exhaust gas discharged through the damper unit (500).

Meanwhile, the damper unit (500) may be configured to be openable and closable, but it may not be completely shut off and may be in constant communication with the exhaust flow path (231) and a heat exchange module (80) described later. Accordingly, since it is in constant communication with the heating space (S2) and the internal space (S3) communicating with the heating space (S2), the interior can be maintained at high pressure, and high-temperature exhaust gas can be transferred.

The cooling gas supply unit (400) is a component installed through the opening/closing part to supply cooling gas to the inside of the outer tube (300), and various configurations are possible.

In this case, the cooling gas supply unit (400) may supply cooling gas to the heating space (S2) for cooling the heating space (S2).

In this case, the cooling gas supply unit (400) may be installed through the opening/closing part to supply cooling gas to the heating space (S2). More specifically, it may be installed from outside to penetrate the lower side of the flange part (320) and connect to the heater unit (200).

For example, the cooling gas supply unit (400) may include an external supply pipe (410) installed on the lower side of the flange part (320) to transfer cooling gas from outside, and an internal supply pipe (420) installed inside the flange part (320) so as to communicate with the external supply pipe (410), with one end coupled to the side of the heater unit (200) and the other end coupled to the inner surface of the flange part (320).

The external supply pipe (410) is a component installed by being coupled to the lower side of the flange part (320) to transfer cooling gas from outside, and various configurations are possible.

In this case, the cooling gas supplied through the external supply pipe (410) is external air, and the external supply pipe (410) can open and close a valve (430) provided at its end to receive external air and transfer it to the internal gas supply pipe (420).

Further, as another example, the external supply pipe (410) may be connected to a separately provided cooling gas supply source (not shown) with a valve (430) interposed therebetween, to receive cooling gas at a flow rate controlled by the valve (430) and supply it to the internal supply pipe (420).

In this case, the external supply pipe (410) may be installed to be coupled to the bottom surface of the rectangular flange part (320). More specifically, it may be installed to extend laterally from the flange part (320) so as not to protrude to the opposite side of the vessel part (310) with respect to the flange part (320) in a plane.

That is, the external supply pipe (410) may be formed in an ‘L’ shape in front view with respect to the opening/closing door part (330), which has the advantage of increasing space efficiency and enabling the application of a compact apparatus structure.

The internal supply pipe (420) is a component installed inside the flange part (320) to communicate with the external supply pipe (410), with one end coupled to the side of the heater unit (200) and the other end coupled to the inner surface of the flange part (320). Various configurations are possible.

That is, as shown in FIG. 2, the internal supply pipe (420) is a component that communicates with the external supply pipe (410) and transfers cooling gas to the heater unit (200) side, and at least a portion thereof may be disposed within the flange part (320).

For example, the internal supply pipe (420) may include a first internal supply pipe forming a flow path for cooling gas transfer therein and coupled to the aforementioned connecting flange, and a second internal supply pipe having one end coupled to the first internal supply pipe and the other end corresponding to the external supply pipe (410) and coupled to the inner surface of the flange part (320) for installation.

In this case, the second internal supply pipe is disposed between the bottom surface of the hexahedral first internal supply pipe and the inner surface of the flange part (320), thereby transferring cooling gas supplied from the bottom surface of the flange part (320) to the first internal supply pipe, and guiding the cooling gas to move horizontally through the first internal supply pipe to the heater unit (200) side.

Meanwhile, the internal supply pipe (420) can transfer cooling gas to the heating space (S2) via the groove (201) and the side insulation part (210) through coupling with the aforementioned connecting flange. In this case, a separate flow path may be formed in the vertical direction of the side insulation part (210) so that the cooling gas is evenly transferred toward the heating space (S2) in the vertical direction of the side insulation part (210).

Meanwhile, the internal supply pipe (420) may be coupled at a height corresponding to the boundary between the side insulation part (210) and the upper insulation part (230) so as to communicate with the heating space (S2). Also, as described above, it may be coupled at a position corresponding to the groove (201) formed on the outer side of the side insulation part (210) with an inward step, and communicating with the heating space (S2).

Further, the internal supply pipe (420) may be disposed below the damper unit (500) inside the flange part (320).

Meanwhile, the cooling gas supply unit (400) including the external supply pipe (410) and the internal supply pipe (420) may be provided as a pair in both lateral directions with respect to the front center of the flange part (320), and in this case, the external supply pipes (410) may extend in opposite directions to each other.

In this case, the external supply pipe (410) and the internal supply pipe (420) may be formed as a symmetrical pair with respect to the center of the damper unit (500) and the opening/closing door part (330) in front view.

The cooling unit (600) is a component provided on at least a portion of the outer surface of the outer tube (300) and having heat medium flowing therein. Various configurations are possible.

For example, the cooling unit (600) may be installed in contact with the outer surface of the vessel part (310) and configured to have heat medium flowing therein, and can lower the temperature of the vessel part (310) through heat exchange between the heat medium and the vessel part (310).

Furthermore, the cooling unit (600) may be configured to surround and extend along the side of the flange part (320) to cool the flange part (320), and if necessary, it may also be further extended and installed on the side flange (360).

For example, the cooling unit (600) may include a first cooling pipe (610) provided on the outer surface of the outer tube (300) and having heat medium flowing therein, and a second cooling pipe (620) extending from the first cooling pipe (610) and installed to surround at least a portion of the flange part (320) and having heat medium flowing therein.

Accordingly, the first cooling pipe (610) and the second cooling pipe (620) can form a single heat medium flow path.

In this case, the heat medium is supplied to the second cooling pipe (620) of the flange part (320), which has relatively high temperature due to the installation of the damper unit (500), flows along the second cooling pipe (620), then continuously flows through the first cooling pipe (610), and is discharged to an external heat exchanger to increase cooling efficiency.

The foregoing is merely a description of some of the preferred embodiments that can be implemented by the present invention. As is well known, the scope of the present invention should not be construed as being limited to the above embodiments, and it is understood that all technical ideas that share the technical spirit and fundamental principles of the present invention described above are included within the scope of the present invention.

What is claimed is:

1. A substrate processing apparatus comprising: an inner tube forming a processing space in which a plurality of substrates are stacked and processed in a vertical direction;
a heater unit installed to surround at least a portion of the inner tube to form a heating space between itself and the inner tube, and generating heat by receiving power from outside; and
an outer tube in which the heater unit is disposed to form an internal space between itself and the heater unit, and having at least one openable/closable opening formed on a side thereof to allow external access to the internal space, wherein the heater unit is electrically connected to a power supply unit that transfers power through the outer tube at a position corresponding to the opening.

2. The substrate processing apparatus according to claim 1, wherein:
the heater unit has its connection part with the power supply unit exposed when the opening is opened.

3. The substrate processing apparatus according to claim 1, wherein:
the heater unit includes a side insulation part disposed to surround the inner tube, a heating part provided on the inner surface of the side insulation part to generate heat according to the applied power, and a terminal part provided on the outer surface of the side insulation part and electrically connected to both ends of the heating part.

4. The substrate processing apparatus according to claim 3, wherein:
the terminal part is provided at a height corresponding to the opening.

5. The substrate processing apparatus according to claim 3, wherein:
the terminal part includes a connection terminal provided on the outer surface of the side insulation part to be coupled to the heating part, and a connection rod extending from the connection terminal to the opening side and coupled to the power supply unit.

6. The substrate processing apparatus according to claim 5, wherein:
the connection rod is extended such that an end thereof, which is coupled to the power supply unit from the connection terminal provided at a position offset from the opening, is located at a position corresponding to the opening.

7. The substrate processing apparatus according to claim 5, wherein:
the connection terminal and the connection rod are integrally formed.

8. The substrate processing apparatus according to claim 3, wherein:
the opening is formed at a height corresponding to the terminal part.

9. The substrate processing apparatus according to claim 5, wherein:
a plurality of the connection terminals are disposed to overlap in a planar direction in the vertical direction; and
the connection rod includes at least one of a horizontal rod extending in a horizontal direction and a vertical rod extending in a vertical direction to prevent overlap with the remaining connection terminals except for the extended connection terminal.

10. The substrate processing apparatus according to claim 3, wherein:
a plurality of the terminal parts are provided; and
at least one is provided per heating region for a plurality of heating regions separated in a vertical direction.

11. The substrate processing apparatus according to claim 10, wherein:
a plurality of the terminal parts correspond to a single opening.

12. The substrate processing apparatus according to claim 10, wherein: t
he opening is provided in a plurality of units in a vertical direction on the outer surface of the outer tube.

13. The substrate processing apparatus according to claim 1, wherein:
the outer tube includes a vessel part forming the internal space and having the opening formed on a side thereof, a side flange provided in the vessel part at a position corresponding to the opening, and a door part installed on the side flange to open and close the opening.

14. The substrate processing apparatus according to claim 1, wherein:
the outer tube includes at least one first connector part provided on a side thereof, to which the power supply unit is connected to transfer power from outside to the heater unit.

15. The substrate processing apparatus according to claim 14, wherein: the first connector part electrically connects an external power supply line connected from outside the outer tube of the power supply unit, and an internal power supply line disposed and connected in the internal space.

16. The substrate processing apparatus according to claim 1, wherein:
the outer tube includes at least one second connector part provided on a side thereof for electrical connection between a temperature sensor installed to penetrate the heater unit and the outside.

17. The substrate processing apparatus according to claim 1, further comprising:
a cooling unit provided on at least a portion of the outer surface of the outer tube and having heat medium flowing therein.

18. The substrate processing apparatus according to claim 1, wherein:
the internal space and the heating space communicate with each other.

19. The substrate processing apparatus according to claim 1, wherein:
the inner tube comprises quartz; and the outer tube comprises SUS.

20. The substrate processing apparatus according to claim 1, wherein:
the internal space is maintained at higher pressure than the processing space.

21. The substrate processing apparatus according to claim 1, wherein:
the heating space maintains temperature of 800° C. or more during at least a portion of the process performed in the processing space.

22. The substrate processing apparatus according to claim 1, wherein: the internal space maintains pressure of 2 ATM or more during at least a portion of the process performed in the processing space.
